(19) United States
(12) Patent Application Publication
(10) Pub. No.: US 2014/0353025 A1
(43) Pub. Date: Dec. 4, 2014

(54) PRINTED CIRCUIT BOARD

(71) Applicant: SAMSUNG ELECTRO-MECHANICS CO., LTD., Suwon (KR)

(72) Inventors: Deok Suk JANG, Suwon (KR); Yong Sam Lee, Yongin (KR)

(73) Assignee: SAMSUNG ELECTRO-MECHANICS CO., LTD., Suwon (KR)

(21) Appl. No.: 14/224,728

(22) Filed: Mar. 25, 2014

(30) Foreign Application Priority Data
May 29, 2013 (KR) 10-2013-0061086

(51) Int. Cl. H05K 1/11; H05K 13/00

(52) U.S. Cl. CPC H05K 1/116; H05K 13/00
USPC 174/262; 29/829

(57) ABSTRACT

A printed circuit board includes a first insulating layer; a pad formed on the first insulating layer; a second insulating layer covered on the first insulating layer having the pad thereon; and a via hole formed in the second insulating layer. The pad has a surface that is non-planar.

### CROSS-REFERENCE TO RELATED APPLICATIONS

This application claims the foreign priority benefit under 35 U.S.C. Section 119 of Korean Patent Application Serial No. 10-2013-0061086, filed May 29, 2013 in the Korean Intellectual Property Office, the disclosure of which is hereby incorporated by reference in its entirety into this application.

### BACKGROUND

1. Field

Embodiments of the present invention relate to a printed circuit board, and more particularly, to a printed circuit board with improved electrical connection reliability.

2. Description of the Related Art

In general, a printed circuit board (PCB) plays a role of electrically connecting mounted components through a circuit pattern formed on an insulating material such as a phenolic insulation board or an epoxy resin insulation board and mechanically fixing the components while supplying power etc. The PCBs can be classified into three types: a single-sided PCB in which a circuit layer is formed only on one surface of an insulating substrate, a double-sided PCB in which circuit layers are formed on both surfaces of an insulating substrate, and a multilayered board (MLB) in which wirings are formed in a plurality of layers.

A subtractive method, an additive method, a semi-additive method, and a modified semi-additive method are known as a method of forming a circuit pattern on a PCB, and a circuit pattern can be formed on one or both surfaces of an insulating material by these methods.

However, as the pattern of the PCB becomes finer, a fine circuit can no longer be formed by the subtractive method. Therefore, in order to implement a fine circuit, there is an increasing tendency to use a SAP method.

In general, in a process of forming a circuit pattern by a SAP method, an insulating material having a copper foil on one surface thereof is provided, a via hole is formed in the insulating material, and a seed layer is formed on one surface of the insulating material and the inner wall of the via hole. After that, a plating layer is formed by an electroplating process and patterned to form a circuit pattern.

At this time, the via hole is formed by processing the insulating mainly using laser, and then the seed layer and the plating layer are formed. However, since a pad is not exposed inside the via hole and the via hole is processed not to be completely perforated due to a resin residue generated in the process of forming the via hole, the plating layer filled in the via hole may not be electrically connected to the pad.

Further, there is a disadvantage that the adhesion between the top surface of the pad and the plating layer filled in the via hole is deteriorated due to the residue formed on the pad inside the via hole.

### CITATIONS

Korean Patent Laid-open Publication No. 2011-0049247

### SUMMARY

Embodiments of the present invention have been invented in order to overcome the above-described problems and it is, therefore, an aspect of such embodiments of the present invention to provide a printed circuit board having a via with improved electrical connection reliability.

In accordance with one aspect of the present invention to achieve the object, there is provided a printed circuit board including: a first insulating layer; a pad formed on the first insulating layer; a second insulating layer covered on the first insulating layer having the pad thereon; and a via hole formed in the second insulating layer, wherein the bottom of the via hole, which is formed in the second insulating layer, on the pad may be a non-planar surface having an uneven shape.

At this time, the first insulating layer may be one of a core and an insulating layer built up on the core.

Further, a seed layer may be formed on the inner wall of the via hole, and a plating layer may be filled inside the seed layer.

And, the pad may be a portion of circuit layers formed on the first insulating layer and the second insulating layer, and a nickel/gold (Ni/Au) plating layer may be further formed on the surface of the pad.

The via hole may be formed by irradiating a short pulse laser having a peak power, whose beam intensity in the outer portion is higher than that in the center portion, to process the second insulating layer and a portion of the top surface of the pad at the same time.

Further, the non-planar surface of the via hole on the pad, which forms the bottom, may consist of a convex surface and a concave surface, wherein the concave surface may be formed in the shape of a ring around the convex surface.

Additional aspects and/or advantages will be set forth in part in the description which follows and, in part, will be apparent from the description, or may be learned by practice of the invention.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a printed circuit board in accordance with embodiments of the present invention;

FIG. 2 is a partial enlarged cross-sectional view of the printed circuit board shown in FIG. 1;

FIG. 3 is a plan view of the partial enlarged cross-sectional view shown in FIG. 2 and a plan view of a via hole before a plating layer is formed;

FIG. 4 is a view schematically showing a profile of a short pulse laser irradiated to the printed circuit board of the present embodiment;

FIG. 5 is a cross-sectional view of a printed circuit board in accordance with another embodiment of the present invention;

FIG. 6 is a plan view of the printed circuit board in accordance with another embodiment of the present invention;

FIG. 7 is a view schematically showing a profile of a short pulse laser irradiated to the printed circuit board of the present embodiment;

FIG. 8 is a cross-sectional view of a printed circuit board in accordance with still another embodiment of the present invention; and

FIG. 9 is a plan view of the printed circuit board in accordance with still another embodiment of the present invention.

### DESCRIPTION OF EMBODIMENTS

A matter regarding to an operational effect including a technical configuration for an object of a printed circuit board in accordance with embodiments of the present invention will be clearly appreciated through the following detailed description with reference to the accompanying drawings showing embodiments of the present invention.

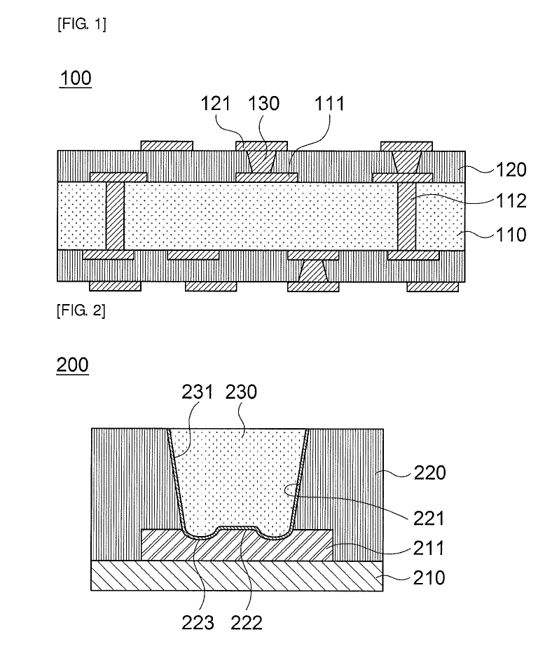

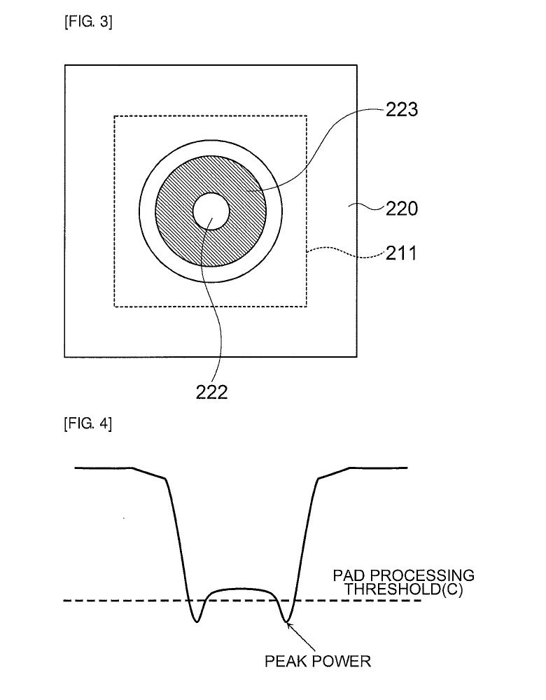

First, FIG. 1 is a cross-sectional view of a printed circuit board in accordance with embodiments of the present invention, FIG. 2 is a partial enlarged cross-sectional view of the printed circuit board shown in FIG. 1, and FIG. 3 is a plan view of the partial enlarged cross-sectional view shown in FIG. 2. At this time, FIG. 3 is a plan view of a via hole before a plating layer is formed.

As shown, in a printed circuit board 100 in accordance with embodiments of the present invention, inner circuit layers 111 may be formed on the top and bottom of a core 110 made of an insulating material, insulating layers 120 having outer circuit layers 121 thereon may be laminated on one or both surfaces of the core 110, and the inner circuit layer 111 and the outer circuit layer 121 formed on the core 110 and the insulating layer 120 may be electrically connected through a via 130. Further, the inner circuit layers 111 formed on the top and bottom of the core 110 may be electrically connected through a through hole 112 formed through the core 110.

The printed circuit board 100 may be a multilayer printed circuit board formed by continuously building up the insulating layer 120 formed on the core 110 according to the designed number of layers, and the circuit layers 121 formed on the respective insulating layers 120 may be conducted through the vias 130 formed in the respective insulating layers 120.

And the core 110 may be formed of a copper clad laminate (CCL) having copper foils laminated on both surfaces thereof, and the circuit layer 111 may be formed through a process of patterning a plating layer by separately plating copper foil layers on both surfaces of the insulating material.

At this time, the via 130 may be formed with the through hole 112 formed in the core 110 by mechanical processing using CNC drilling or laser processing using laser drilling. However, currently, as the printed circuit board becomes thinner and smaller, the via is mainly processed using laser according to the demand for a fine pitch of the circuit layer.

Among the laser processing methods as above, a laser processing method using CO₂ laser is mainly used, and by the via processing method using CO₂ laser, only the insulating layer 120 is perforated and the metal layers, particularly the circuit layers 111 and 121 made of copper (Cu), are not processed so that the top surface of a pad constituting the circuit layer is exposed through an opening of the via 130. However, in the past, as the laser beam is irradiated to the top surface of the circuit layer mainly in the shape of ‘∇’, since the residue of the insulating layer may be left on the exposed side surface of the pad, a process of removing the residue by a separate desmear process may be further added after forming the via, and the reliability of connection between the plating layer formed inside the via 130 and the circuit layers 111 and 121 may be improved by removing the residue.

Further, in the conventional laser processing method, since the top surface of the pad constituting the circuit layer inside the via 130 is not processed by laser and thus becomes a planar surface, a separate process of forming a roughness may be performed to improve the reliability of connection with the plating layer which fills the inside of the via 130.

In order to prevent the addition of the separate process for improving the connection reliability of the via like this, the bottom of a via hole 221 formed in the insulating layer 220 may be formed as a non-planar surface as shown in FIGS. 2 and 3. At this time, the bottom of the via hole 221 may be formed on the top surface of the pad 211.

More specially describing with reference to the cross-sectional view and the plan view shown in FIGS. 2 and 3, a printed circuit board 200 in accordance with embodiments of the present invention includes a first insulating layer 210, a pad 211 formed on the first insulating layer 210, a second insulating layer 220 covered on the first insulating layer 210 having the pad 211 thereon, and a via hole 221 formed in the second insulating layer 220, wherein the bottom of the via hole 221, which is formed in the second insulating layer 220, on the pad 211 may be a non-planar surface having a predetermined uneven shape.

At this time, the first insulating layer 210 may be the core 110 or the insulating layer 120 built up on the core 110 shown in FIG. 1, and the pad 211 may be a portion of the inner or outer circuit layer 121 formed on each insulating layer 120 including the core in the printed circuit board described with reference to FIG. 1.

Further, a plating layer 230 may be filled in the via hole 221 formed in the second insulating layer 220. It is preferred that the plating layer 230 is made of a conductive material to enable the electrical connection between the pad 211 formed on the first insulating layer 210 and another pad (not shown in the drawing) formed on the second insulating layer 220, and a seed layer 231 may be further formed inside the plating layer 230. The seed layer 231 may be formed on the surface of the second insulating layer 220 including the inner wall of the via hole 221 at the same time to improve the adhesion between the plating layer 230 and the insulating layer as well as to facilitate the formation of the plating layer 230 when forming the plating layer 230 inside the via hole 221 and on the second insulating layer 220.

As described above, the via hole 221 may be processed by laser so that the sidewall thereof forms a predetermined slope. However, the sidewall of the via hole 221 may be formed to be perpendicular to the top surface of the pad 211 formed on the first insulating layer 220 according to the type of the laser beam or the angle of the irradiated laser beam without being limited to the slope.

Further, the via hole 221 may be processed by laser so that the top surface of the pad 211 is exposed through an upper opening and thus the top surface of the pad 211 forms the bottom of the via hole 221. At this time, the top surface of the pad 211, which is the bottom of the via hole 221, may be formed as a non-planar surface. When processing the via hole 221 using the laser irradiated from above the second insulating layer 220, the laser beam passes through the second insulating layer 220 and the end of the laser beam is partially irradiated to the top surface of the pad 211 so that the top surface of the pad 211 is formed as a non-planar surface having a predetermined uneven structure.

At this time, the pad 211 may constitute the circuit layer formed by forming a copper foil layer on the first insulating layer 210 after forming the first insulating layer 210 and patterning the copper foil layer through etching. In some cases, a nickel/gold (Ni/Au) plating layer may be further formed on the surface of the pad 211 constituting the circuit layer to draw an appropriate adhesion performance when bonding a solder ball.

As the laser to process the via hole 221 in the present embodiment, a short pulse laser whose beam intensity in the outer portion is higher than that in the center portion as shown in FIG. 4 is used to process the second insulating layer 220 and a portion of the top surface of the pad 211 at the same time.

That is, when the short pulse laser with a peak power in the outer portion than the center portion is irradiated, the second insulating layer 220 is processed by the laser beam within a pad processing threshold C formed in the center portion of the laser beam, and a temperature in the portion of the top surface of the pad 211 is raised by the laser beam higher than the pad processing threshold C formed in the outer portion of the laser beam so that the top surface of the pad 211 is processed.

Accordingly, the top surface of the pad 211, that is, the bottom of the via hole 221 can consist of uneven convex surface 222 and concave surface 223 having different depths in the center portion and the outer portion. More specifically, the center portion of the circular bottom of the via hole 221 forms the convex surface 222 and the outer portion thereof is processed by the peak power of the short pulse laser to form the concave surface 223 so that the concave surface 223 can be formed on the bottom in the shape of a ring as shown in FIG. 3.

Here, FIG. 4 is a view schematically showing a profile of the short pulse laser irradiated to the printed circuit board of the present embodiment.

The seed layer 231 may be further formed inside the via hole 221 configured as above, and the seed layer 231 may include the convex surface 222 and the concave surface 223 of the bottom of the via hole 222 as well as the sidewall of the via hole 221. And the plating layer 230 may be filled in the via hole 221 to be bonded to the seed layer 231. The plating layer 230 may be made of a metal conductive material which is equal/similar to the material of the seed layer 231, and the plating layer 230 may be made of the same metal material as the seed layer 231 in order to improve the reliability of adhesion between the pad 211 formed on the first insulating layer 210 and the pad 211 formed on the second insulating layer 220.

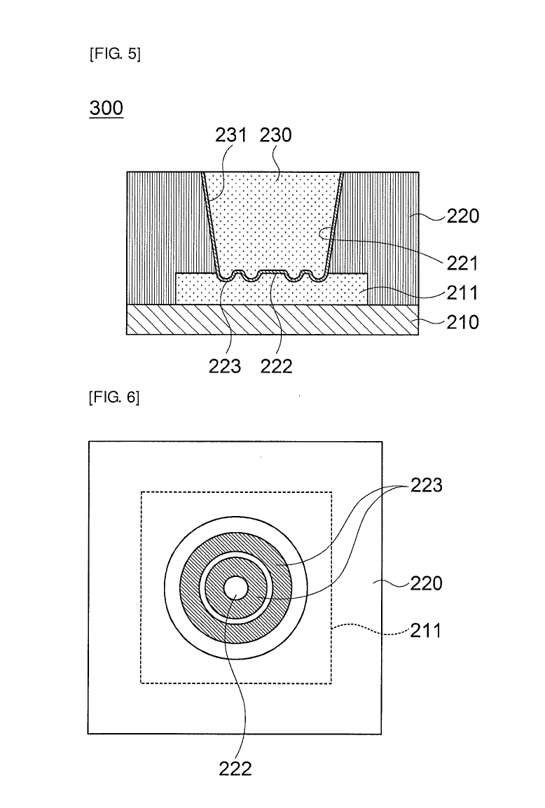

Meanwhile, FIGS. 5 and 6 are a cross-sectional view and a plan view of a printed circuit board in accordance with another embodiment of the present invention. Hereinafter, detailed descriptions overlapping with those of the above-described embodiment will be omitted, and the same components are represented by the same reference numerals.

As shown, a printed circuit board 300 in accordance with the present embodiment includes a first insulating layer 210, a pad 211 formed on the first insulating layer 210, a second insulating layer 220 covered on the first insulating layer 210 having the pad 211 thereon, and a via hole 221 formed in the second insulating layer 220, wherein a plurality of ring-shaped convex surfaces 222 and concave surfaces 223 may be formed on the pad 211 which forms the bottom of the via hole 221 formed in the second insulating layer 220.

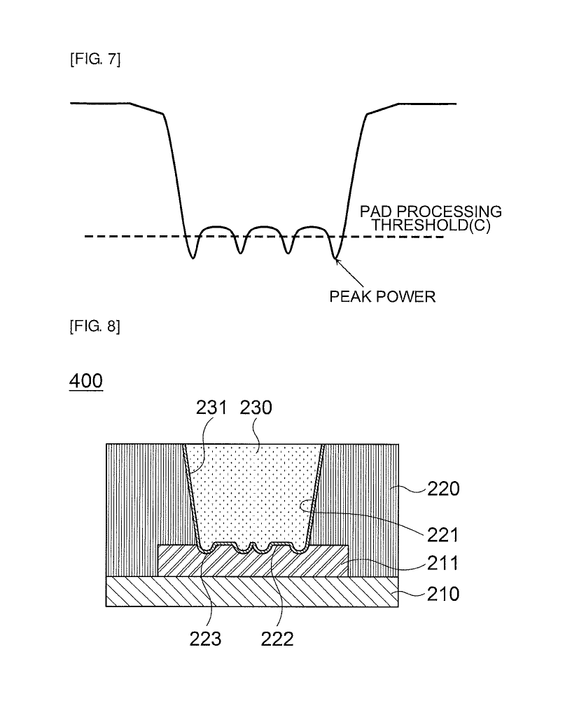

That is, when a short pulse laser having peak powers of different diameters based on a pad processing threshold C shown in FIG. 7, the second insulating layer 220 and the top surface of the pad 211 are processed at the same time and the laser beam higher than the pad processing threshold C is irradiated to the top surface of the pad 211 to process the top surface of the pad 211.

At this time, the plurality of ring-shaped concave surfaces 223 of different diameters may be formed on the top surface of the pad 211 by the laser beam higher than the pad processing threshold C, and the convex surface 222 may be formed in the center of the plurality of concave surfaces 223 in the shape of a circular target.

Like this, the concave surfaces 223 processed on the pad 211 on the bottom of the via hole 221 in the shape of a plurality of rings may be processed using the short pulse laser having peak powers of different diameters shown in FIG. 7. However, the concave surface 223 in the outer portion of the pad 211 may be processed using the short pulse laser having a peak power in the outer portion thereof shown in FIG. 4 and the inner concave surface 223 may be formed by reducing the diameter of the laser beam to irradiate the laser beam again, so that the concave surfaces 223 of different diameters can be formed.

Here, FIG. 7 is a view schematically showing a profile of the short pulse laser irradiated to the printed circuit board of the present embodiment.

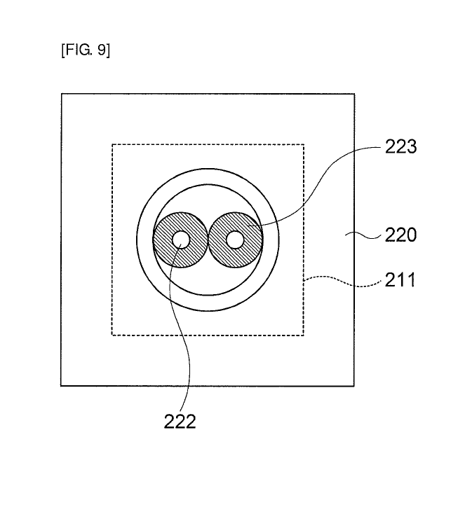

Meanwhile, FIGS. 8 and 9 are a cross-sectional view and a plan view of a printed circuit board in accordance with still another embodiment of the present invention.

As shown, a printed circuit board 400 in accordance with this further embodiment includes a first insulating layer 210, a pad 211 formed on the first insulating layer 210, a second insulating layer 220 covered on the first insulating layer 210 having the pad 211 thereon, and a via hole 221 formed in the second insulating layer 220, wherein a convex surface 222 and a concave surface 223 may be formed on the pad 211, which forms the bottom of the via hole 221 formed in the second insulating layer 220, in the shape of a plurality of rings and the ring-shaped convex surface 222 and concave surface 223 may be formed in parallel.

At this time, the plurality of rings formed on the pad 211 on the bottom of the via hole 221 may be processed by adjusting the diameter of a laser beam having a peak power in the outer portion thereof as shown in FIG. 4, and the diameter of the laser beam may be adjusted not to overlap the concave surfaces 223 with each other in the plurality of rings formed in parallel. Further, the concave surfaces 223 may be overlapped with each other during processing, and when the concave surfaces 223 are overlapped with each other, the diameter of the convex surface 222 may be relatively increased than when the concave surfaces 223 aren't overlapped with each other.

Although not shown in the drawings, the cross-sectional shape of the concave surface 223 formed on the pad 211 on the bottom of the via hole 221 described in the above-described embodiments may be a horizontal surface or a curved surface projecting in the shape of a semicircle and may consist of a horizontal surface and a curved surface selectively according to the thickness of the pad 211 and the depth of the concave surface 223. Further, the cross-sectional shape of the concave surface 223 may be selected considering the reliability of adhesion with a plating layer 230 filled in the via hole 221.

Further, a seed layer 231 may be formed along the inner wall of the via hole 221, and the plating layer 230 may be filled inside the via hole 221. The seed layer 231 and the plating layer 230 may be made of the same metal material, and it is preferred that the seed layer 231 and the plating layer 230 are made of the same material as the pad 211 considering the conduction with the pads 211 connected to the top and bottom thereof.

The printed circuit boards in accordance with the above embodiments can improve the efficiency of adhesion between the plating layer 230 filled inside the via hole 221 and the pad 211 by processing the via hole 221 using a short pulse laser so that a portion of the top surface of the pad 211 has a predetermined non-planar uneven shape, compared to the related art in which only an insulating layer is perforated using a typical CO₂ laser without processing of the bottom of a via hole, which is formed of a pad.

As described above, the printed circuit board in accordance with embodiments of the present invention can improve the connection failure between the pad and the plating layer due to the resin residue by processing the via hole to a predetermined depth of the top surface of the pad using a short pulse laser to remove all the resin residue when forming the via hole.

Further, the printed circuit board of embodiments of the present invention can effectively increase the adhesion between the pad and the plating layer by forming a non-planar surface on the top surface of the pad, which forms the bottom of the via hole, using a short pulse laser when processing the via hole.

The above-described exemplary embodiments of the present invention are disclosed for the purpose of exemplification and it will be appreciated by those skilled in the art that various substitutions, modifications and variations may be made in these embodiments without departing from the technical spirit of the present invention. Such substitutions and modifications are intended to be included in the appended claims.

What is claimed is:

1. A printed circuit board comprising:
a first insulating layer;
a pad formed on the first insulating layer;
a second insulating layer on the first insulating layer; and
a via hole formed in the second insulating layer,
wherein the bottom of the via hole is on the pad and is a non-planar surface having an uneven shape.

2. The printed circuit board according to claim 1, wherein the first insulating layer is one of a core and an insulating layer built up on a core.

3. The printed circuit board according to claim 1, wherein a seed layer is formed on an inner wall of the via hole, and a plating layer is filled inside a space defined by the seed layer.

4. The printed circuit board according to claim 1,
wherein the pad is a portion of circuit layers formed on the first insulating layer and the second insulating layer,
further comprising a nickel/gold (Ni/Au) plating layer formed on the surface of the pad.

5. The printed circuit board according to claim 1, wherein the via hole is formed by irradiating a short pulse laser having an intensity profile in which a peak power is at an outer portion of the profile and is higher than an intensity in a central portion of the profile, to process the second insulating layer and a portion of the top surface of the pad at the same time.

6. The printed circuit board according to claim 1, wherein the non-planar surface on the pad which forms the bottom of the via hole includes a convex surface and a concave surface.

7. The printed circuit board according to claim 6, wherein the concave surface is formed in the shape of a ring.

8. The printed circuit board according to claim 6, wherein
the concave surface is formed in the shape of a ring and encircles the convex surface, and
the ring-shaped concave surface and the convex surface collectively cover substantially the entire surface of the pad within the via hole.

9. The printed circuit board according to claim 7, wherein the cross-sectional shape of the bottom of the concave surface is selectively one of a horizontal surface and a curved surface.

10. The printed circuit board according to claim 3, wherein the seed layer is formed on the inner wall of the via hole including the convex surface and the concave surface at the bottom of the via hole.

11. The printed circuit board according to claim 6, wherein the seed layer is formed on the inner wall of the via hole including the convex surface and the concave surface.

12. The printed circuit board according to claim 6, wherein the concave surface is formed in the shape of a plurality of rings.

13. The printed circuit board according to claim 12, wherein the via hole is formed by irradiating a short pulse laser having peak powers at different diameters exceeding a processing threshold of the pad, to process the second insulating layer and a portion of the top surface of the pad at the same time.

14. The printed circuit board according to claim 12, wherein the plurality of rings include a first-shaped concave surface and a second ring-shaped concave encircling the first ring-shaped concave surface.

15. The printed circuit board according to claim 12, wherein the ring-shaped concave surfaces of the non-planar surface are disposed in parallel.

16. A method of manufacturing the printed circuit board of claim 1, comprising:
irradiating a short pulse laser having an intensity profile in which a peak power is at an outer portion of the profile and is higher than an intensity in a central portion of the profile,
thereby forming the via hole and the non-planar surface.

17. A printed circuit board comprising:
an insulating layer;
a via hole formed in the insulating layer;
a pad having a non-planar surface facing the end portion of the via hole, the non-planar surface having portions recessed into the pad; and
a conductive filling that is filling at least an end portion of the via hole and is attached to the non-planar surface of the pad.

18. The printed circuit board according to claim 17, wherein the non-planar surface includes a ring-shaped portion recessed into the pad.

19. The printed circuit board according to claim 17, wherein the non-planar surface includes a plurality of ring-shaped portions recessed into the pad.

20. The printed circuit board according to claim 18, wherein the plurality of ring-shaped portions include a first ring-shaped portion and a second ring-shaped portion encircling the first ring-shaped portion.

21. A method of manufacturing a printed circuit board, comprising:
irradiating a portion of an insulating layer covering over a pad with a pulsed laser to form a via hole through the insulating layer and a recess in the pad, the pulsed laser having an intensity profile in which intensity at an outer portion of the profile is greater than a processing threshold of the pad and greater than an intensity at a central portion of the profile.
